(19) United States
(12) Patent Application Publication
(10) Pub. No.: US 2007/0152684 A1
(43) Pub. Date: Jul. 5, 2007

(54) Apparatus and method for analyzing photo-emission

(75) Inventors: Ho-Jin Lee, Yongin-si (KR); Chan-Soon Park, Seongnam-si (KR); Duck-Young Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/647,287

(22) Filed: Dec. 29, 2006

(30) Foreign Application Priority Data
Dec. 31, 2005 (KR) 10-2005-0136264

(51) Int. Cl. G01R 31/308

(52) U.S. Cl. 324/753; 324/512

(57) ABSTRACT

A photo-emission analysis apparatus may include a plate, a socket board on the plate, and configured to receive semiconductor chip package. The apparatus may further include a housing on the plate, the housing having an inlet configured to introduce air into the housing, and a photon detector configured external to the housing.

### PRIORITY CLAIM

A claim of priority is made to Korean Patent Application No. 10-2005-0136264, filed on Dec. 31, 2005, in the Korean Intellectual Property Office, the disclosure of which is incorporated herein in its entirety by reference.

### BACKGROUND

1. Field

Example embodiments may relate to an apparatus and method for inspecting defects in semiconductor packages, for example, to a photo-emission analysis apparatus and method for analyzing a semiconductor package.

2. Description of the Related Art

Integrated circuit (IC) chips which may be manufactured by a series of semiconductor manufacturing processes may be further assembled into semiconductor chip packages by a packaging process. To check electrical properties and reliability of semiconductor chip packages, the semiconductor chip packages may undergo a variety of quality tests. The quality tests may include a burn-in test, a humidity test, a highly accelerated stress test (HAST), etc., and may be performed under an artificially controlled environment. Semiconductor chip packages that fail to pass the quality test processes may be screened and may undergo further tests to analyze or identify defects that may have caused the failure.

A test for analyzing defects may include a quiescent (inactive) supply current test. Generally, no or very little of current flows in a normal transistor during a quiescent state. A quiescent supply current test may analyze a semiconductor chip package in a quiescent state by detecting abnormal current flow. The abnormal current may be detected by a photo-emission analysis.

In a metal oxide semiconductor (MOS) IC chip, very small current, e.g., leakage current, may flow through a PN junction of a MOS transistor. However, when there is a defect, for example, a latch up or junction collapse in the PN junction, larger amounts of current may flow, even in the quiescent state. The abnormal current flow may generate ultraviolet rays from the PN junction. A photo-emission analysis using a photon detector may determine the location of the defect by detecting the ultraviolet rays. By determining the location of the defect, the process point where the defect may have been generated or a problem in the design may be identified.

When the quiescent supply current test is performed on a failed semiconductor chip package under an environment identical or similar to the quality test, the cause of the defect may be accurately determined. For example, when the quiescent supply current test is performed on a semiconductor chip package applied with heat, which is similar to a thermal stress quality test, the location of the defect generated at a specific temperature and the process whereby the defect may have been generated or a problem in the design may be identified.

FIGS. 1A and 1B are perspective views illustrating conventional methods of applying heat to semiconductor packages. Generally, heat may be applied in a manner consistent with the type of package for a photo-emission analysis.

Referring to FIGS. 1A and 1B, conventional semiconductor chip packages, for example, thin small outline package (TSOP) type package 100a and ball grid array (BGA) type package 100b may include a protective housing 102a, 102b, wherein an IC chip (not shown) may be provided therein. A plurality of leads 101a extending outwardly from the protective housing 102a or a plurality of contact points configured on solder balls 101b may be formed on the outer surface of the protective housing 102b, respectively. The IC chip provided in the protective housing 102a and 102b may be electrically connected by the plurality of leads 101a and contact points of the solder balls 101b. The semiconductor chip packages 100a and 100b may be inserted in socket boards 51a and 51b, respectively, which may be designed specifically for the type of the semiconductor chip package. In order to perform the quiescent supply current test, an electrical signal may be applied to the respective IC chip in the semiconductor chip packages 100a and 100b using a signal generator 80 connected by a connector wire 81 to the socket board 50a and 50b.

To perform the quiescent supply current test on the semiconductor chip packages 100a and 100b at a specific temperature, heat may be applied to the semiconductor chip package 100a and 100b using adapted heating units. For example, a heat guider 60a configured to provide heat conduction and heating a gun 60b configured to blow heated air may be used.

However, it may be difficult to handle the heat guider 60a when the semiconductor chip packages 100a and 100b are inserted in the socket board 50a, 50b. Furthermore, when the heat is being supplied via the heat guider 60a, heat loss may occur, and therefore a uniform temperature may not be applied to the semiconductor chip packages 100a and 100b.

The heating gun 60b may be easier to handle when the semiconductor chip packages 100a and 100b are inserted in the socket board 50a, 50b; however, it may be difficult to precisely heat the semiconductor chip packages 100a and 100b. Furthermore, the heating gun 60b may overheat and damage the photo-emission analysis apparatus.

### SUMMARY

Example embodiments may provide a photo-emission analysis apparatus that may provide an environment identical or similar to that of a quality test regardless of a type of a semiconductor chip package.

Example embodiments may also provides a photo-emission analyzing method that may provide an environment identical or similar to that for a quality test regardless of a type of a semiconductor chip package.

In an example embodiment, a photo-emission analysis apparatus may include a plate, a socket board on the plate and configured to receive semiconductor chip package, a housing on the plate, the housing having an inlet configured to introduce air into the housing, and a photon detector external to the housing.

In another example embodiment, a photo-emission analysis method may include providing a housing for a semiconductor chip package mounted in a socket board to isolate the semiconductor chip package from an exterior environment of the housing, supplying air into the housing through an inlet formed on the housing, applying an electrical signal to the socket board, and detecting light emitted from the semiconductor chip package.

### BRIEF DESCRIPTION OF THE DRAWINGS

The above and other features of example embodiments may become more apparent with the description of the example embodiments thereof with reference to the attached drawings in which:

FIG. 1A is a perspective view of a device for applying heat to a thin small outline package (TSOP) in a photo-emission analysis of the conventional art;

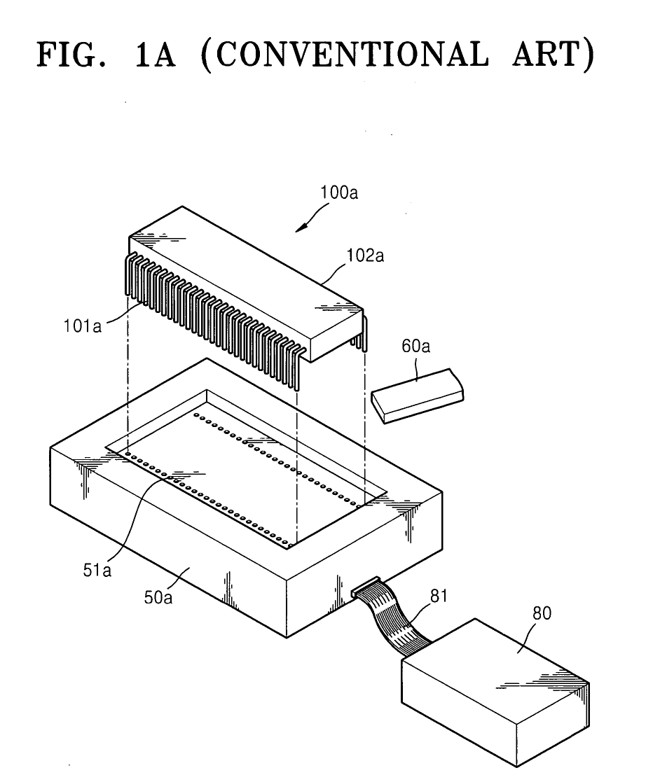

FIG. 1B is a perspective view of a device for applying heat to a ball grid array package (BGAP) in a photo-emission analysis of the conventional art;

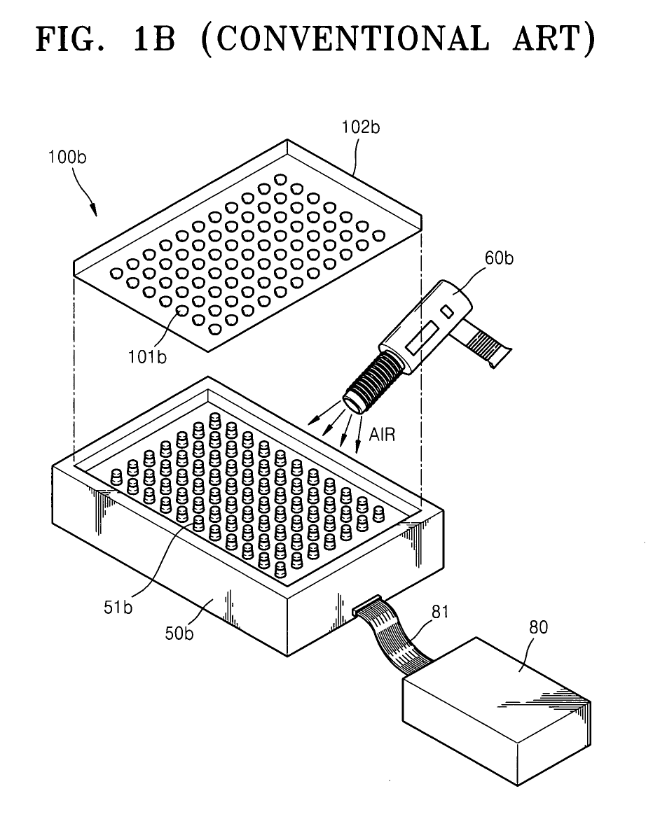

FIG. 2 is a perspective view of an opened photo-emission analysis apparatus according to an example embodiment; and

FIG. 3 is a perspective view of a closed photo-emission analysis apparatus according to an example embodiment.

### DETAILED DESCRIPTION OF EXAMPLE EMBODIMENTS

Example embodiments will now be described more fully with reference to the accompanying drawings. Example embodiments may, however, be embodied in many different forms and should not be construed as being limited to the example embodiments set forth herein; rather, example embodiments are provided so that this disclosure will be thorough, and will fully convey the concept of the example embodiments to those skilled in the art. In the drawings, the thicknesses of layers and regions may be exaggerated for clarity. Like reference numerals in the drawings denote like elements, and thus their description will be omitted.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

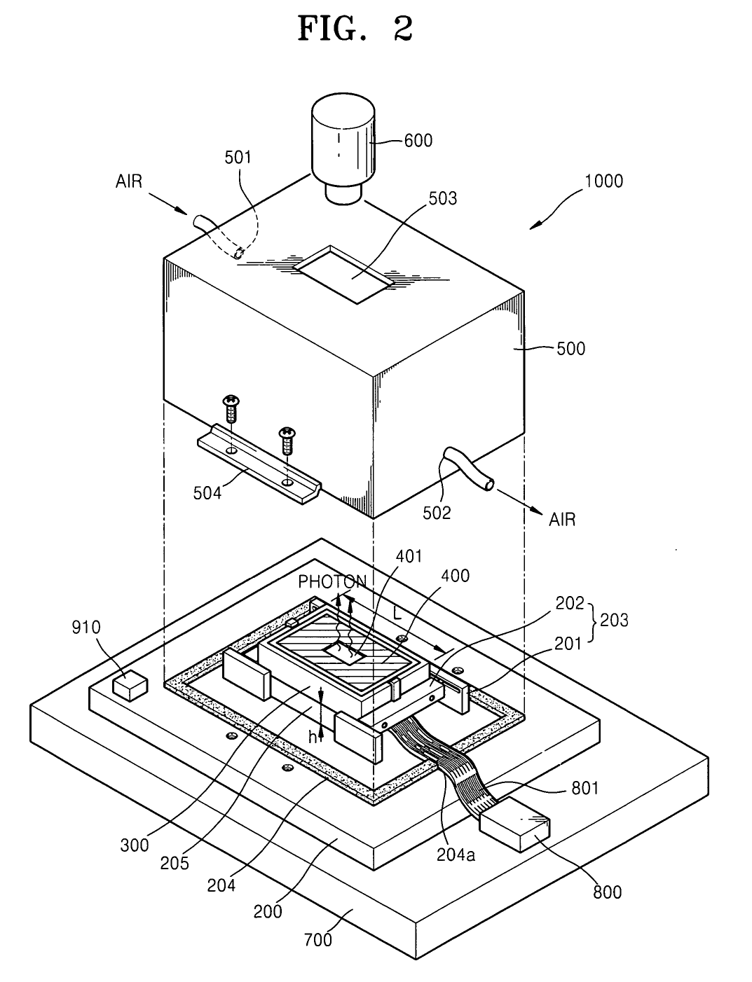

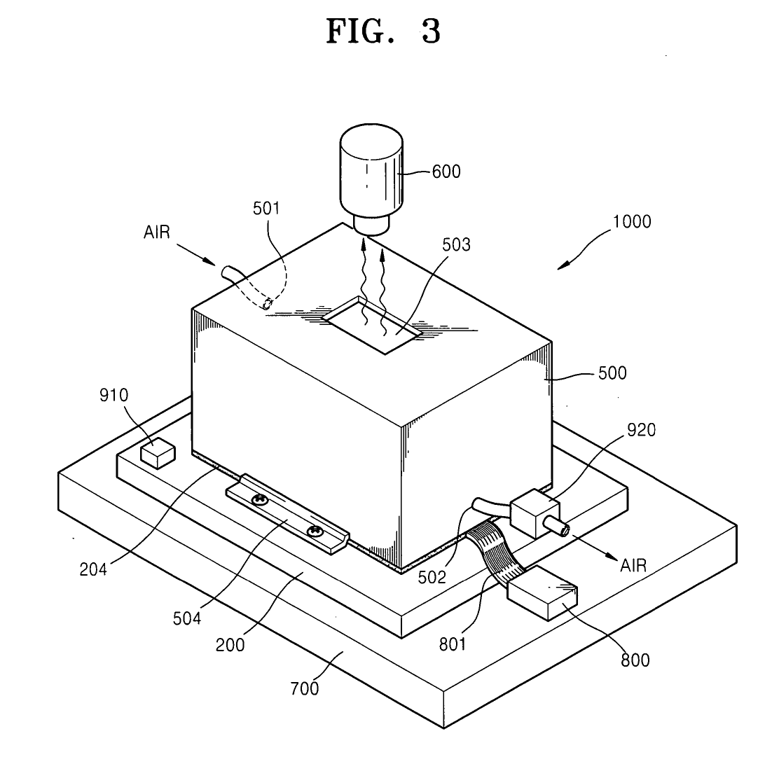

FIG. 2 and FIG. 3 are perspective views of an opened and closed photo-emission analysis apparatus 1000, respectively, according to example embodiments.

Referring to FIG. 2, the photo-emission analysis apparatus 1000 may include a plate 200, and a socket board 300 provided on the plate 200, in which a semiconductor chip package 400 may be mounted. A housing 500 may be arranged on the plate 200, and a photon detector 600 may be provided external to the housing 500 to detect emitted light from the semiconductor chip package 400. The photo-emission analysis apparatus 1000 may further include a signal generator 800. The signal generator 800 may provide a signal corresponding to an actual operation signal of an IC chip to the semiconductor chip package 400 or a signal for testing a quiescent supply current.

The plate 200 may be designed to detach or be fixed on a probe station 700. The plate 200 may have a desired strength required to support the socket board 300 and the housing 500.

The socket board 300 may be designed in a variety of shapes and sizes to accommodate a specific type of semiconductor chip package 400. The photo-emission analysis apparatus 1000 may further include a height adjusting unit 205 to adjust height h of the socket board 300 and a first fixing unit 203. The first fixing unit 203 may fix the socket board 300. For example, the height adjusting unit 205 may include a block having a desired height.

The first fixing unit 203 may include a fastener 202 to couple the plate 200 and socket board 300, and a fixing guide 201 to adjust a gap distance L of the fastener 202 accordingly to a size of the socket board 300. The fastener 202 may be a screw or clamp coupling unit. The photo-emission analysis apparatus 1000 may position any type of semiconductor chip package, regardless of the size and height of the socket board 300 due to the first fixing unit 504.

The housing 500 may be disposed on the plate 200. The housing 500 may isolate the semiconductor chip package 400 from the external environment of the housing 500. The housing 500 may be tightly coupled with the plate 200 to effectively enclose the socket board 300 therein. The photo-emission analysis apparatus 1000 may further include a second fixing unit 504 to fix the housing 500 to the plate 200. The second fixing unit 504 may include a fastener, for example, a screw or clamp coupling unit, which may be similar to the first fixing unit 203.

The photo-emission analysis apparatus 1000 may further include a heat insulation member 204, for example, an insulating sponge, interposed between the plate 200, and the housing 500. A connector wire 801 to apply an electric signal may be provided through a hole 204a that may be formed in one of the housing 500 and/or the plate 200 or between the plate 200 and the housing 500. When the connector wire 801 passes through the hole 204a formed in the heat insulation member 204, heat within the housing 500 may be maintained and the damage to the connector wire 801 may be reduced or prevented. As a result, the internal environment of the housing 500 may not be affected by the conditions, for example, temperature, humidity, etc., of the external environment of the housing 500. Therefore, the internal environment of the housing 500 may be identical or substantially similar to that of the quality control test so as to more accurately analyze the cause of the defects.

Referring to FIG. 3, the housing 500 may be provided with an inlet 501 through which heated or cooled air may be introduced to adjust the temperature of the interior of the housing 500. In the photo-emission analysis apparatus 1000, air may be used as a thermal medium to control the temperature of the interior of the housing 500. When heated air is introduced through the inlet 501, the temperature of the interior of the housing 500 may increase. When cooled air is introduced through the inlet 501, the temperature of the interior of the housing 500 may decrease. A temperature detection unit 910 may be provided to measure the temperature of the interior of the housing 500 and to measure the temperature of the semiconductor chip package 400.

A thermo stream device (not shown), well known in the field of electrical property testing of IC chips, may also be used to supply the air, for example, the thermal medium through the inlet portion 501. The thermo stream device may be used to calculate the temperature margin required for the IC chip and may supply air having a temperature in a range of around −60 to 300° C.

The housing 500 may be further provided with an outlet 502 through which the introduced air may be exhausted out of the housing 500. As a result, the air may be cycled continuously in the housing 500 to thereby more uniformly maintain the temperature of the interior of the housing 500. In example embodiments, a steady airflow state may be maintained from the inlet 501 to the outlet 502. Accordingly, the temperature distribution of the interior of the housing 500 may be more uniformly maintained, and thus the temperature of the semiconductor chip package 400 may be equivalent to that of the introduced air.

In order to maintain the airflow in the steady state and constant internal pressure, the air introduced through the inlet 501 may be intermittently or continuously exhausted out of the housing 500 through the outlet 502. An airflow control unit 920 may be provided on the outlet 502 to maintain the airflow in the steady state. The airflow control unit 920 may be an airflow regulator having a pressure sensor or a pressure valve exhausting air when pressure increases to a critical level.

The housing 500 may also include an observing window 503 through which the photon detector 600 may detect the light emitted from the semiconductor chip package 400. The observing window 503 may be formed of transparent glass capable of transmitting visible light and infrared light. For example, the observing window 503 may be formed of glass that may transmit visible and infrared light of wavelengths in the range of about 1,100-5,000 nm.

The photon detector 600 may include an optical system (not shown) and a charge coupled device (CCD) camera (not shown). In order to perform the photo-emission analysis, the semiconductor chip package 400 may be provided with an opening, which may define an observing region 401 (see FIG. 2) corresponding to a region where the IC chip may be mounted. A test signal generated by the signal generator 800 may be sent to the semiconductor chip package 400 through the socket board 300. The light generated from the observing region 401 of the semiconductor chip package 400 may be transmitted through the observing window 503, and thus the light may be incident on the photon detector 600.

According to example embodiments, because air may be used as the thermal medium, a photo-emission analysis may be performed at various temperatures. When the photo-emission analysis is performed at lower temperatures, condensation due to the humidity may cause leads or contact points to short circuit. However, in example embodiments, a housing enclosing a semiconductor chip package may effectively block humidity, thereby preventing any short circuits.

The photo-emission analysis apparatus according to example embodiments may be applied to test a variety of semiconductor packages, for example, a dual inline package (DIP), a quad flat package (QFP), a chip scale package (CSP), and as well as TSOP and BGAP.

According to example embodiments, because a designed environment identical or similar to the quality tests for the semiconductor chip package may be provided by using a housing isolating a semiconductor chip package from an external environment, the cause of defects may be more effectively identified. Furthermore, because air may be used as the thermal medium, the photo-emission analysis may be performed at various temperatures regardless of the type of semiconductor chip package tested.

While example embodiments have been particularly shown and described, it will be understood by those of ordinary skill in the art that various changes in form and details may be made therein without departing from the scope of example embodiments as defined by the following claims.

What is claimed is:

1. A photo-emission analysis apparatus comprising:
a plate;
a socket board on the plate, and configured to receive a semiconductor chip package;
a housing on the plate, the housing having an inlet configured to introduce air into an interior of the housing; and
a photon detector configured external to the housing.

2. The photo-emission analysis apparatus of claim 1, wherein the housing is sealed with the plate.

3. The photo-emission analysis apparatus of claim 2, further comprising an insulation member disposed between the plate and the housing.

4. The photo-emission analysis apparatus of claim 1, further comprising a height adjusting unit configured to adjust a height of the socket board based on a type of the semiconductor chip package.

5. The photo-emission analysis apparatus of claim 4, further comprising a first fixing unit configured to fix the socket board to the plate.

6. The photo-emission analysis apparatus of claim 5, wherein the first fixing unit includes a fastener configured to couple the plate and the socket board, and a fixing guide configured to fix the socket board.

7. The photo-emission analysis apparatus of claim 5, further comprising a second fixing unit configured to fix the housing to the plate.

8. The photo-emission analysis apparatus of claim 7, wherein the second fixing unit includes a screw coupling unit or a clamp coupling unit.

9. The photo-emission analysis apparatus of claim 1, further comprising a signal generator configured to provide a signal to the semiconductor chip package.

10. The photo-emission analysis apparatus of claim 1, wherein the housing further includes an outlet configured to exhaust the air from the interior of the housing.

11. The photo-emission analysis apparatus of claim 10, further including an airflow control unit connected to the outlet and adapted to control an internal pressure of the housing.

12. The photo-emission analysis apparatus of claim 1, further including an air supplying unit connected to the inlet.

13. The photo-emission analysis apparatus of claim 12, wherein the air supplying unit includes a thermo stream device.

14. The photo-emission analysis apparatus of claim 1, wherein the housing includes an observing window through which light emitted from the semiconductor package is incident on the photon detector.

15. The photo-emission analysis apparatus of claim 14, wherein the observing window includes glass configured to transmit visible light and infrared light.

16. The photo-emission analysis apparatus of claim 1, further comprising a temperature detection unit configured to detect an internal temperature of the housing.

17. A photo-emission analysis method comprising:
providing a housing for a semiconductor chip package mounted in a socket board to isolate the semiconductor chip package from an exterior environment of the housing;
supplying air into the housing through an inlet formed on the housing;
applying an electrical signal to the socket board; and
detecting light emitted from the semiconductor chip package.

18. The photo-emission analysis method of claim 17, further comprising supplying the air into the housing to maintain an internal temperature of the housing at a desired level.

19. The photo-emission analysis method of claim 18, wherein a flow of the air in the housing is maintained in a steady state.

20. The photo-emission analysis method of claim 18, further comprising exhausting the air supplied into the housing out of the housing to maintain the internal pressure of the housing at a desired level.
